(19) United States
(12) Patent Application Publication
(10) Pub. No.: US 2002/0042021 A1
(43) Pub. Date: Apr. 11, 2002

(54) Interleaving paper for radiation sensitive planographic printing plates

(76) Inventors: Hiroshi Okano, Oura-gun (JP); Yasuhiko Kojima, Oura-gun (JP)

Correspondence Address: RATNER & PRESTIA, P.O. Box 7228, Wilmington, DE, 19803, US

(21) Appl. No.: 09/927,182

(22) Filed: Aug. 10, 2001

(30) Foreign Application Priority Data
Aug. 16, 2000 (JP) P2000-247043

(51) Int. Cl. G03F 7/09

(52) U.S. Cl. 430/273.1; 430/302

(57) ABSTRACT

An interleaving paper for laser exposable radiation sensitive planographic printing plate precursors having a radiation sensitive layer is disclosed. The interleaving paper has a stiffness of 100 g or higher and a stiffness per unit thickness of 2.0 g/μm or higher. The interleaving paper can be easily removed by an automatic interleaving paper releasing machine. The printing plate precursor can be made efficiently, even when the interleaving paper is placed directly on the radiation sensitive layer of a laser exposable radiation sensitive planographic printing plate precursor that does not have a mat layer formed thereon. The interleaving paper can also be manufactured at a lower cost. Use of the interleaving paper makes it possible to reduce the distribution cost of the printing plate precursors.

### BACKGROUND OF THE INVENTION

1. Field of the Invention

The present invention relates to an interleaving paper for laser exposable radiation sensitive planographic printing plates.

2. Description of Related Art

In the prior art, image formation on a radiation sensitive printing plate has been carried out by exposing the printing plate to radiation through a master film that bears the image, then removing the non-exposed portions (negative working) or removing the exposed portions (positive working).

Before exposing the radiation sensitive printing plate to radiation, the radiation sensitive printing plate and the master film are brought into close contact with each other by evacuating the air from the space therebetween, in order to achieve complete contact between the master film and the surface of the radiation sensitive layer of the printing plate. In this method, if the surface of the radiation sensitive layer of the radiation sensitive printing plate is smooth, it becomes difficult to uniformly evacuate the space between the radiation sensitive printing plate and the master film, thus requiring a longer time to bring the master film into contact with the entire surface of the radiation sensitive layer. Therefore, a process wherein a mat layer is formed by depositing particles of a water-soluble resin or the like on the radiation sensitive layer of the radiation sensitive printing plate, to efficiency pump out the air from the space between the radiation sensitive layer of the radiation sensitive printing plate and the master film through the gaps between the particles, has been employed to thereby bring both sheets into contact with each other in a shorter time.

The radiation sensitive printing plate is typically marketed with sheets of interleaving paper placed on its radiation sensitive layer with a mat layer between the two, and a multitude of sheets is stacked one on top of another. The interleaving paper is provided to protect the radiation sensitive layer. The interleaving paper protects the radiation sensitive layer from damage even when a multitude of radiation sensitive printing plates are stacked one on top of another.

The interleaving paper is removed from the radiation sensitive layer before the process of exposing the radiation sensitive printing plate. Because the radiation sensitive layer has the mat layer formed thereon, the interleaving paper does not stick too strongly to the radiation sensitive layer, so that it can be released easily by an automatic interleaving paper releasing machine. The automatic interleaving paper releasing machine may be of a type that releases the interleaving paper by moving it with a rubber roller or the like, or a type that releases the interleaving paper by blowing a pressurized gas, or a type that has a suction pad or the like to draw away and release the interleaving paper.

Recently, a laser exposable radiation sensitive planographic printing plate has been developed that allows formation of an image directly on a printing plate without using a master film, by irradiating it with a laser beam. Because an image can be formed on the laser exposable radiation sensitive planographic printing plate without using the master film, the radiation sensitive layer typically does not have a mat layer formed thereon and the interleaving paper is placed directly on the radiation sensitive layer.

However, when the interleaving paper is placed directly on the radiation sensitive layer, the contact area between the radiation sensitive layer and the interleaving paper becomes larger and the sheets stick to each other. When the interleaving paper and the radiation sensitive layer stick to each other, it becomes difficult to release the interleaving paper by means of the automatic interleaving paper releasing machine and problems arise, such as paper jamming in the automatic interleaving paper releasing machine, thus resulting in a substantial decrease in the efficiency of print making.

### SUMMARY OF THE INVENTION

An object of the present invention is to provide interleaving paper for laser exposable radiation sensitive planographic printing plates that can be easily released by an automatic interleaving paper releasing machine.

The interleaving paper for the radiation sensitive planographic printing plates of the present invention is an interleaving paper used for laser exposable radiation sensitive planographic printing plates having a stiffness of 100 g or higher, and a stiffness per unit thickness of 2.0 g/μm or higher. When using this interleaving paper, the interleaving paper can be easily released by the automatic interleaving paper releasing machine and print making can be efficiently carried out even when the interleaving paper is placed directly on the radiation sensitive layer of the laser exposable radiation sensitive planographic printing plate that does not have a mat layer formed thereon. The interleaving paper can also be manufactured at a lower cost. Also, use of the interleaving paper makes it possible to reduce the distribution cost of the printing plates.

### BRIEF DESCRIPTION OF THE DRAWING

FIG. 1 shows the method of measuring the stiffness of the interleaving paper.

### DETAILED DESCRIPTION OF THE INVENTION

The present invention will be described in detail below.

The interleaving paper for radiation sensitive planographic printing plates of the present invention is an interleaving paper placed on or over the radiation sensitive layer of a laser exposable radiation sensitive planographic printing plate.

The laser exposable radiation sensitive planographic printing plate, sometimes called a printing plate precursor, is a planographic printing plate comprising a supporting substrate which bears a radiation sensitive layer formed thereon, which is exposed to laser radiation generated by a He-Ne laser, an Ar ion laser, a YAG laser, a He-Cd laser, a semiconductor laser, a ruby laser or the like.

The radiation sensitive layer may be formed from an ordinary radiation sensitive material such as a photopolymerizable composition containing a compound having an ethylenically unsaturated double bond and a photopolymerization initiator, or a crosslinking composition containing a polymeric binder, a photo acid generator, a crosslinking agent, etc., or a positive working composition containing a polymeric binder and a light-to heat converting material. A water-soluble oxygen screening layer may also be provided on the radiation sensitive layer.

The supporting substrate may have a conventional constitution, such as a plate of a metal such as aluminum, zinc, copper, stainless steel or iron; a film of a plastic such as polyethylene terephthalate, polycarbonate, polyvinyl acetal or polyethylene; a composite material comprising paper or a plastic film which is coated with a molten synthetic resin or a solution of synthetic resin and then covered by a metal layer formed by vapor deposition, lamination or other techniques; or other materials which are used for supporting substrates of printing plates. In the case of a supporting substrate having a surface covered by a metal, particularly aluminum, the radiation sensitive layer may also be provided after applying a surface treatment such as sand blasting, anodic oxidation or hydrophilization.

The interleaving paper is provided to protect the radiation sensitive layer of the laser exposable radiation sensitive planographic printing plate described above. The interleaving paper for radiation sensitive planographic printing plates of the present invention has a stiffness of 100 g or higher, and a stiffness per unit thickness of 2.0 g/μm or higher.

The stiffness here refers to the sum of the bending resistance and the frictional resistance, which can be measured by means of, for example, a Handle-O-Meter tactile measurement instrument manufactured by Kumagai Riki Kogyo Co., Ltd. Specifically, the stiffness is measured by the procedure described below.

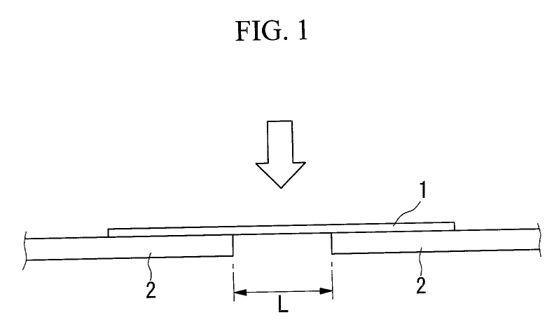

As shown in FIG. 1, a test piece 1 cut into a rectangular shape is supported on support plates 2 without restriction at both ends in the longitudinal direction thereof. A load is applied to the test piece 1 at the center thereof in the direction indicated by the arrow, so as to bend the test piece 1 which, in response thereto, develops a bending resisting force. Although the deflection is small in the early stages of bending and the test piece 1 behaves in a manner similar to that observed in ordinary bending tests, further bending causes slippage between both ends of the test piece 1 and the support plates which results in a frictional force. When the load is increased further, the test piece 1 becomes unable to resist the load and slips off the support plates 2 to fall therebetween.

The stiffness (g) can be represented by the critical load which is above what can be borne by the test piece 1, and is the sum of the bending strength and the friction strength. The stiffness per unit thickness (g/μm) is the stiffness measured as described above divided by the thickness of the test piece 1.

The test piece 1 is made by cutting the interleaving paper into a rectangular shape measuring 5.7 mm in width and 22.9 mm in length, with the fibers of the paper running in the direction of the width of the test piece 1. The support plates 2 are placed with ¼ inch of clearance L therebetween.

Interleaving paper with a stiffness of less than 100 g as measured by the method described above is not sufficiently rigid, and, when placed on the radiation sensitive layer of a laser exposable radiation sensitive planographic printing plate that does not have a mat layer formed thereon, sticks to the radiation sensitive layer and is not readily released by the automatic interleaving paper releasing machine. When stiffness per unit thickness is less than 2.0 g/μm, the paper must be made thicker in order to achieve a level of stiffness that allows releasing by the automatic interleaving paper releasing machine. Making the paper thicker leads to a higher manufacturing cost of the interleaving paper. Moreover, for an automatic interleaving paper releasing machine of a type which removes the interleaving paper by means of a suction pad or the like and transfers the removed interleaving paper by using suction force, the interleaving paper may fall off. Since the interleaving paper is usually removed immediately before making the printing plate, if the interleaving paper falls off while it is being transferred, problems may occur in the manufacturing process, and the efficiency of print making is decreased. Also, if a multitude of radiation sensitive planographic printing plates are stacked with thick interleaving paper sheets therebetween, the stack occupies a greater volume, which increases the unit distribution cost of the printing plates.

Thus the use of interleaving paper having a stiffness of at least 100 g and stiffness per unit thickness of at least 2.0 g/μm makes it possible to easily release the interleaving paper from the laser exposable radiation sensitive planographic printing plate by the automatic interleaving paper releasing machine, carry out the print making process efficiently and reduce the manufacturing cost of the interleaving paper and the distribution cost of the printing plates.

The automatic interleaving paper releasing machine may be, besides the type which releases the interleaving paper by drawing the paper away with a suction pad or the like, of a type which removes the interleaving paper by moving it with a rubber roller or the like, or of a type which removes the interleaving paper blowing it with pressurized gas. When the interleaving paper for radiation sensitive planographic printing plates of the present invention is used, the interleaving paper can be easily released from the printing plate regardless of which type of automatic interleaving paper releasing machine is used, and the removed interleaving paper can also be transferred away reliably. If the automatic interleaving paper releasing machine of the suction type is employed, for example, problems such as the interleaving paper falling off during transfer, and jamming of the released paper due to overly strong suction with the suction pad, do not occur.

The interleaving paper preferably has a smoothness of 30 seconds or less on the surface which contacts the radiation sensitive layer of the laser exposable radiation sensitive planographic printing plate. When the smoothness is 30 seconds or less, it is easier to remove the interleaving paper from the laser exposable radiation sensitive planographic printing plate by the automatic interleaving paper releasing machine.

The surface of the interleaving paper that does not contact the radiation sensitive layer of the laser exposable radiation sensitive planographic printing plate, namely the non-contact surface, also preferably has a smoothness of 30 seconds or less. The non-contact surface comes into contact with the support substrate of the printing plate when a plurality of the laser exposable radiation sensitive planographic printing plates are stacked one on another. And the surface of the support substrate is usually smooth. Therefore, release of the interleaving paper from the support substrate can also be improved by making the smoothness of the surface which does not contact the radiation sensitive layer 30 seconds or less. The smoothness is measured in accordance with JIS (Japanese Industrial Standard) P8119. Specifically, a test piece is pressed by constant pressure (1 kgf/cm²) on a circular glass plate having a smooth surface produced by an optical surface finish and having a hole in its central position, and then, the smoothness of the sample piece is estimated by measuring the time required for air (10 cc) to pass through the gap between the sample piece and the glass plate under a decompressed atmosphere. The longer the time required, the smoother the surface.

The interleaving paper for radiation sensitive planographic printing plates of the present invention may be made of any material without restriction as long as the stiffness is 100 g or higher and the stiffness per unit thickness is 2.0 g/μm or higher. For example, the interleaving paper may be made of paper, a nonwoven fabric, a plastic sheet or film, or a laminated sheet or film made by coating paper with resin layer on one or both of the surfaces thereof.

When paper is used, it may be made of mechanical pulp such as a ground pulp which is mechanically processed, a chemical pulp made by chemical processing, or a semi-chemical pulp or chemical ground pulp made by combining both processes. The pulp may also be either pulp bleached at a purification step or non-bleached pulp. Further, paper consisting of chemical fibers such as rayon, nylon, vinylon, polyester, polyacrylonitrile, and/or polystyrene may also be used. Moreover, such papers impregnated with an organic material may also be used without restriction.

### EXAMPLES

The present invention will now be specifically described below by way of examples. In the following examples, percentages are by weight unless otherwise specified.

### Example 1

Aluminum sheets 0.3 mm thick were surface treated by sand blasting and then subjected to anodic oxidation treatment to form an oxide film thereon. TCC-106 radiation sensitive laser exposable planographic printing plates (manufactured by Kodak Polychrome Graphics Japan Ltd.), having a negative working radiation sensitive layer formed on the aluminum sheet, and EL830 radiation sensitive laser exposable planographic printing plates (manufactured by Kodak Polychrome Graphics Company Ltd.), having a positive working radiation sensitive layer formed on the aluminum sheet, were prepared.

The interleaving paper (1), made of 100% paper pulp and having the physical properties shown in Table 1, was attached to the radiation sensitive layers of the printing plates by the electrostatic corona method and then the plates were cut into sheets measuring 1030 mm by 800 mm. A cassette carrying the sheets was mounted on a single cassette auto loader SA-L8000 (manufactured by Dai Nippon Screen Co., Ltd.) for the automatic interleaving paper releasing machine.

Then the automatic interleaving paper releasing machine was operated while observing the state of the release of the interleaving paper (1). The results shown in Table 1 were obtained.

The physical properties of the interleaving paper (1) were measured as follows.

(1) Stiffness

The stiffness was measured by the method shown in FIG. 1 using a Handle-O-Meter tactile measurement instrument manufactured by Kumagai Riki Kogyo Co., Ltd.

The test piece 1 was made by cutting the interleaving paper into a rectangular shape measuring 5.7 mm in width and 22.9 mm in length, with the fibers of the paper running in the direction of the width of the test piece 1. The support plates 2 of the measuring instrument were placed with ¼ inch of clearance L therebetween, with the full scale of the load being set to 100 g.

(2) Smoothness

The smoothness of the surfaces of the interleaving paper, one of which contacted and the other of which did not contact the radiation sensitive layer of the laser exposable radiation sensitive planographic printing plate was measured in accordance with JIS P8119 by using a Bekk smoothness device (trade name of Degibekk tester; a product of Toyo Seiki Seisaku-sho, Ltd). The Bekk smoothness device had a glass plane having an outer diameter of 37.4 mm and an inner diameter of 11.3 mm, a rubber presser bar having a diameter of 45 mm and a thickness of 4 mm, a pressure plate having a diameter of 45 mm, and a vacuum vessel having a volume of 380 L

The test piece was made by cutting the interleaving paper into square shapes measuring 50 mm each side. After leaving the test piece for 1 hour at 23±1° C. in 50±2% RH (relative humidity), the test piece was placed onto the glass plane with the surface to be measured contacting the glass plane, onto which the rubber presser bar and the pressure plate were placed and 100 kPa of pressure was applied by means of a pressure application device. After decreasing the internal pressure of the vessel to 50.7 kPa or less, the time (in seconds) required for 10 ml of air to pass through, that is, the time required for the internal pressure of the vessel to decrease from 50.7 kPa to 48.0 kPa, was measured. Thus, the smoothness of the contact surface of each test piece was measured ten times, and the average smoothness thereof was calculated. In the same manner, the average smoothness of the non-contact surface of each test piece was calculated.

### Comparative Examples 1 to 3

Release tests were conducted in the same manner as in Example 1, except that interleaving papers (2) to (4) were used instead of the interleaving paper (1). Interleaving papers (2) to (4) were made of 100% pulp. The test results are shown in Table 1.

TABLE 1

| | | | Comp. | Comp. | Comp. |
|---|---|---|---|---|---|
| | | Example 1 | Example 1 | Example 2 | Example 3 |
| Type of interleaving | | Interleaving | Interleaving | Interleaving | Interleaving |
| paper | | paper (1) | paper (2) | paper (3) | paper (4) |
| Unit weight (g/m²) | | 41.0 | 48.0 | 36.1 | 34.2 |
| Thickness (μm) | | 57 | 72 | 46 | 48 |
| Stiffness (g) | | 137 | 142 | 90 | 85 |
| Stiffness per unit | | 2.40 | 1.97 | 1.96 | 1.77 |
| thickness (g/μm) | | | | | |
| Smoothness of | | 18 | 25 | 180 | 160 |
| contact surface (sec.) | | | | | |
| Smoothness of non- | | 17 | 11 | 17 | 12 |
| contact surface (sec.) | | | | | |
| Release | TCC-106^{*1} | ∘ | Δ | X | X |
| test | EL830^{*2} | ∘ | Δ | X | X |

^{*1}Negative working laser exposable radiation sensitive planographic printing plate
^{*2}Positive working laser exposable radiation sensitive planographic printing plate.

The symbols used in the Table show the ratings as follows.

◯: 500 sheets of interleaving paper were released satisfactorily.

Δ: One out of about 20 sheets could not be released due to a problem.

×: Release of all sheets of interleaving paper failed, some being broken.

As shown in Table 1, the interleaving paper (1) of Example 1, which has a stiffness of 100 g or higher, a stiffness per unit thickness of 2.0 g/μm or higher, and a smoothness of 30 seconds or less on the contact surface and the non-contact surface is easier to release from the laser exposable radiation sensitive planographic printing plate, and can be released by the automatic interleaving paper releasing machine without any problem.

Having described the invention, we now claim the following and their equivalents.

What is claimed is:

1. A radiation sensitive planographic printing plate precursor comprising, in order: a supporting substrate; a radiation sensitive layer over the supporting substrate; and an interleaving paper over the radiation sensitive layer;
in which:
the interleaving paper has a first surface and a second surface;
the second surface is opposite the first surface;
the first surface of the interleaving paper faces the radiation sensitive layer and supporting substrate;
the interleaving paper has a stiffness of 100 g or higher and a stiffness per unit thickness of 2.0 g/μm or higher.

2. The precursor of claim 1 in which the first surface of the interleaving paper has a smoothness of 30 seconds or less.

3. The precursor of claim 2 in which the second surface of the interleaving paper has a smoothness of 30 seconds or less.

4. The precursor of claim 3 in which the printing plate precursor does not have a mat layer formed thereon.

5. The precursor of claim 1 in which the first surface of the interleaving paper is in contact with the radiation sensitive layer.

6. The precursor of claim 5 in which the first surface of the interleaving paper has a smoothness of 30 seconds or less.

7. The precursor of claim 6 in which the second surface of the interleaving paper has a smoothness of 30 seconds or less.

8. The precursor of claim 7 in which the printing plate precursor does not have a mat layer formed thereon.

9. The precursor of claim 1 in which the interleaving paper comprises a material selected from the group consisting of paper, non-woven fabrics, plastic sheets, and resin laminated paper.

10. The precursor of claim 9 in which the first surface of the interleaving paper has a smoothness of 30 seconds or less, and in which the second surface of the interleaving paper has a smoothness of 30 seconds or less.

11. The precursor of claim 1 in which the radiation sensitive layer comprises either (1) a photopolymerizable composition comprising a photopolymerization initiator and a compound having an ethylenically unsaturated double bond, or (2) a crosslinking composition comprising a polymeric binder, a photo acid generator, and a crosslinking agent.

12. The precursor of claim 11 in which the first surface of the interleaving paper has a smoothness of 30 seconds or less, and in which the second surface of the interleaving paper has a smoothness of 30 seconds or less.

13. The precursor of claim 1 in which the radiation sensitive layer comprises a polymeric binder and a light to-heat converting material.

14. The precursor of claim 13 in which the first surface of the interleaving paper has a smoothness of 30 seconds or less, and in which the second surface of the interleaving paper has a smoothness of 30 seconds or less.

15. The precursor of claim 1 in which the printing plate precursor does not have a mat layer formed thereon.

16. A method for forming an image, the method comprising the steps of:
(a) providing a radiation sensitive planographic printing plate precursor comprising, in order: a supporting substrate; a radiation sensitive layer over the supporting substrate; and an interleaving paper over the radiation sensitive layer;
in which:
the interleaving paper has a first surface and a second surface;
the second surface is opposite the first surface;
the first surface of the interleaving paper faces the radiation sensitive layer and supporting substrate;
the interleaving paper has a stiffness of 100 g or higher and a stiffness per unit thickness of 2.0 g/μm or higher
(b) removing the interleaving paper; and
(c) exposing the radiation sensitive layer with laser radiation.

17. The method of claim 16 in which in which the first surface of the interleaving paper has a smoothness of 30 seconds or less, and in which the second surface of the interleaving paper has a smoothness of 30 seconds or less.

18. The method of claim 17 in which the printing plate precursor does not have a mat layer formed thereon.

19. The method of claim 18 in which the radiation is generated by a He-Ne laser, an Ar ion laser, a YAG laser, a He-Cd laser, a semiconductor laser, or a ruby laser.

20. The method of claim 19 in which the first surface of the interleaving paper is in contact with the radiation sensitive layer.
